(19) United States
(12) Patent Application Publication
(10) Pub. No.: US 2007/0042563 A1
(43) Pub. Date: Feb. 22, 2007

(54) Single crystal based through the wafer connections technical field

(75) Inventors: Yong-Fa A. Wang, Coppell, TX (US); Richard A. Davis, Plano, TX (US)

Correspondence Address: Kris T. Fredrick;Honeywell International Inc., 101 Columbia Rd., P.O. Box 2245, Morristown, NJ, 07962, US

(73) Assignee: Honeywell International Inc.

(21) Appl. No.: 11/208,049

(22) Filed: Aug. 19, 2005

(51) Int. Cl. H01L 21/76

(52) U.S. Cl. 438/424

(57) ABSTRACT

A through-the-wafer (TTW) electrically conductive connection can be produced in a heavily doped substrate. An annular trench is created from one side of the wafer such that the trench almost reaches the second side of the wafer. The annular trench can be filled with an electrically insulating material. Alternatively, an electrically insulating layer can be produced on the sides of the trench which is then filled with any material. After filling the trench, the bottom of the substrate is ground to expose the trench bottom and the front side is polished to expose the trench top. The plug of substrate material inside the annular trench is a TTW electrical connection.

### TECHNICAL FIELD

Embodiments relate to the field of semiconductor processing. Embodiments also relate to creating electrical connections that pass completely through a semiconductor wafer. Embodiments are also related to a heavily doped substrate utilized in conjunction with deep electrically insulating trenches to allow for electrically conducting paths that pass from the front of a silicon wafer to its backside thereof.

### BACKGROUND OF THE INVENTION

Most semiconductor devices are created by patterning the front side of a Silicon (Si) substrate. Usually, the substrate is a thin flat disk of material called a wafer. The patterning creates wires or metal interconnects and tiny electronic devices, such as transistors. The back side of the wafer is largely ignored. Some applications, however, do use the back side of the wafer. One use of the back side is to place electrical contacts on it.

Back side electrical contacts can be produced by creating a through-the-wafer (TTW) connection. A TTW connection is an electrically conductive path that goes from the front side of a wafer, where the devices lie, to the back side. One common requirement is that the connection be large, perhaps 20 micrometers (um) in diameter or more. Currently, TTW connections are created by etching a deep hole, filling it with heavily doped polysilicon (polySi) or a metal conductor and then thinning the back side. The following example describes a method for producing TTW connections.

FIG. 1, labeled “prior art”, illustrates an edge on view of a bare silicon wafer 101. The following example starts with a bare Si wafer for convenience. In reality, many devices can already exist on the Si wafer.

FIG. 2, labeled as “prior art”, illustrates the Si wafer 101 after oxidation. The oxidation produces an oxide layer on the front side 201 and an oxide layer on the back side 202. Oxidation is a process by which oxygen reacts with a material. For example, iron oxidizes to become rust. Similarly, Si oxidizes to become Silicon Dioxide, also called glass or oxide. The surface of a Si wafer exposed to normal air will naturally oxidize over time. Semiconductor process engineers, however, know many ways to control how quickly the Si oxidizes and how thick the oxide layer is.

FIG. 3, labeled “prior art”, illustrates the Si wafer 101 of FIG. 2 with a layer of resist 301 deposited over the oxidized front side 201. Resist, sometimes referred to as “photoresist”, is a photosensitive material used in a process called photolithography that is commonly used for patterning semiconductor wafers. It is relatively easy to create patterns in resist because resist reacts to light. Patterning resist, also known as photolithography, is a process for creating patterned resist that includes, but is not limited to, shining a light through a pattern mask onto a resist layer and then developing the resist.

FIG. 4, labeled as “prior art”, illustrates patterned resist 402. The resist over the future location 401 of the TTW connection has been removed by means of the photolithographic development process.

FIG. 5, labeled as prior art, illustrates a deep hole 501 etched into the Si wafer 101. Etching is a well known process in semiconductor processing for selectively removing material. In the example, the material that was not protected by resist or oxide was removed. There are many different etching processes such as wet etch, reactive ion etch (RIE), and plasma etching.

FIG. 6, labeled as “prior art”, illustrates the patterned Si wafer 101 with the resist and the oxide stripped. An insulating oxide 601 is normally deposited or thermally grown on the wafer to provide isolation from the wafer to the TTW connection.

FIG. 7, labeled as “prior art”, illustrates the patterned wafer 101 after polySi 701 deposition. The polySi 701 completely fills the hole 501 in the Si wafer 101. Here, the polySi is heavily doped to increase its electrical conductivity. Doped means that slight amounts of other elements are added to a material to change its properties.

FIG. 8, labeled as “prior art”, illustrates the Si wafer 101 after front side polishing 803 and backside grinding 805. Planarization is a process for polishing or grinding a wafer to produce a flat surface. Here, the front side is polished and the backside is ground to expose a polySi TTW connection 801.

As delivered, unprocessed wafers typically have a front side and a back side. The front side is polished to an extremely high level of smoothness. The backside can be polished or sometimes just lapped or etched to a rough finish. When wafers are processed, devices are usually formed only on the front side. Further polishing of the front side at certain points is a standard step in many semiconductor processing recipes. Back side grinding, which is the removal of some of the bulk silicon from the back of the silicon substrate, is also a common processing step.

Currently, TTW connections are produced using processes similar to that described above. Most notably, they all contain the step of filling the hole with polySi or a similar material. The filling step is a very slow and expensive step. The slowness and expense of the filling step is a barrier to the use of TTW connections in many applications.

The present invention directly addresses the shortcomings of the prior art by etching and filling an annular trench instead of a hole in the Si wafer.

### BRIEF SUMMARY

It is therefore one aspect of the embodiments to deposit a layer of resist over one face of a silicon substrate that is heavily doped. The substrate can be a bare silicon wafer, a processed silicon wafer, some other silicon substrate. A processed wafer is one that has devices, such as wires and transistors, or patterns, doping, and interconnects on it. The silicon substrate is heavily doped so that it has a low resistivity or high conductivity. After the resist layer is deposited, an annular pattern is created in it using standard photolithographic processing.

It is another aspect of the embodiments to etch an annular trench into the silicon substrate as defined by the annular pattern. The trench can then be filled with an electrically insulating material. Using patterned resist to etch patterns into a silicon substrate is a standard process in semiconductor processing. Filling trenches with various materials is also a standard operation in semiconductor processing. Some of those materials are electrically insulating such as silicon oxide, silicon nitride, silicon oxynitride and undoped polysilicon.

It is a further aspect of the embodiments to polish the front side of the silicon substrate and to grind the back side of the silicon substrate. The polishing and grinding steps expose the TTW connection on both sides of the substrate.

It is also another aspect of certain embodiments to create an electrically isolating layer on the trench walls before filling the trench. The electrically isolating layer can be a materials such as oxide. The electrically insulating material can be deposited on the trench walls. Oxide can also be grown on the trench walls via oxidation.

### BRIEF DESCRIPTION OF THE DRAWINGS

The accompanying figures, in which like reference numerals refer to identical or functionally similar elements throughout the separate views and which are incorporated in and form a part of the specification, further illustrate the present invention and, together with the background of the invention, brief summary of the invention, and detailed description of the invention, serve to explain the principles of the present invention.

FIG. 1, labeled “prior art”, shows an edge on view of a bare silicon wafer;

FIG. 2, labeled as “prior art”, shows the Si after oxidation;

FIG. 3, labeled “prior art”, shows the Si wafer of FIG. 1 with a layer of resist deposited on its polished face;

FIG. 4, labeled as “prior art”, illustrates patterned resist;

FIG. 5, labeled as prior art, shows a deep hole etched into the Si wafer;

FIG. 6, labeled as “prior art”, illustrates the patterned Si wafer with the resist and the oxide stripped, and a layer of insulating oxide deposited or grown on the surface.

FIG. 7, labeled as “prior art”, illustrates the patterned wafer after polySi deposition;

FIG. 8, labeled as “prior art”, shows the Si wafer after front side and backside planarization;

FIG. 9 illustrates a silicon substrate, a resist layer, and an annular pattern in accordance with an embodiment;

FIG. 10 illustrates a silicon substrate, a resist layer, and an annular pattern as seen from above in accordance with an embodiment;

FIG. 11 illustrates a substrate, a resist layer, an annular pattern, and an annular trench in accordance with an embodiment;

FIG. 12 illustrates a substrate, an annular trench, an insulating material deposited over the substrate and in the trench in accordance with an embodiment;

FIG. 13 illustrates a substrate, an annular insulator material, and a TTW connection in accordance with an embodiment;

FIG. 14 illustrates a silicon substrate and an annular trench after oxidation in accordance with an embodiment;

FIG. 15 illustrates a substrate and an annular trench after oxidation and after deposition of another material in accordance with an embodiment;

FIG. 16 illustrates a silicon substrate, a filled annular volume, and two annular insulating volumes in accordance with an embodiment; and

FIG. 17 illustrates a silicon substrate, a resist layer, and a rectangular pattern as seen from above in accordance with an embodiment

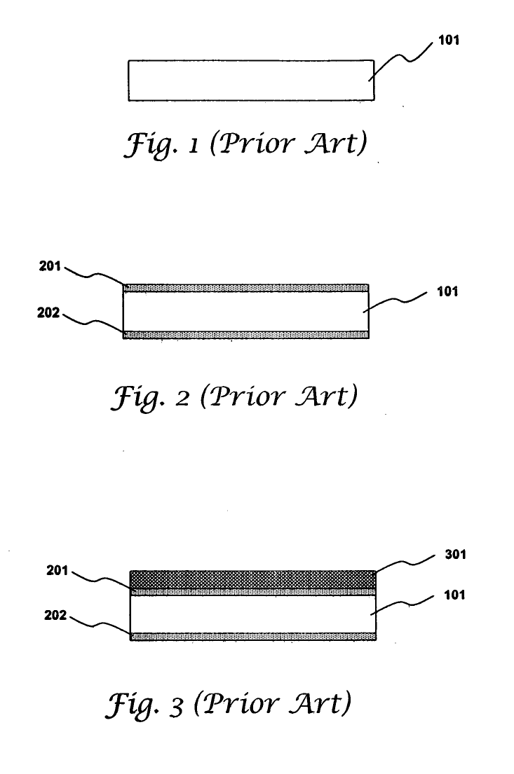

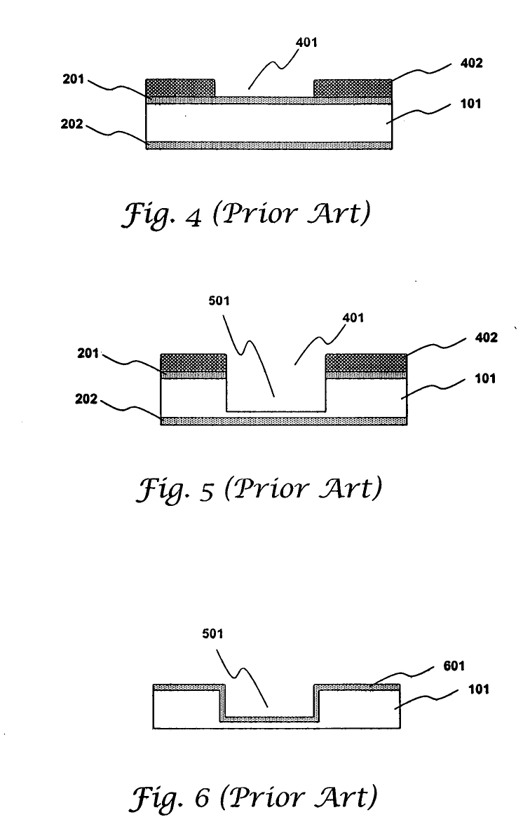

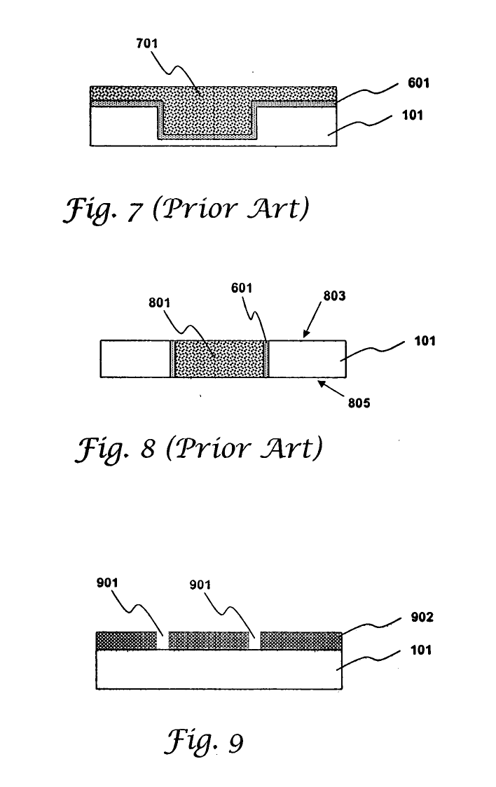

### DETAILED DESCRIPTION

FIG. 9 illustrates a silicon substrate 101 with a patterned resist layer 902 in accordance with an embodiment. The patterned resist layer 902 is a resist layer with an annular pattern 901. The resist layer can be deposited, exposed to an annular light pattern, and developed in accordance with standard photolithographic processing. The result is an annular pattern 901 in the patterned resist layer 902 as shown. As discussed earlier, a bare silicon substrate 101, also called an unprocessed substrate 101, is shown in the illustration to simplify the example. A processed substrate can be used in an alternative embodiment. Furthermore, the substrate 101 becomes a processed substrate at the first processing step, which is usually the deposition of a resist layer.

FIG. 10 illustrates a top view of an annular pattern 901 in a patterned resist layer 902 that would be covering a Si substrate (not shown) in accordance with an embodiment. The difference between FIG. 9 and FIG. 10 is that FIG. 9 is illustrated from a side view while FIG. 10 is illustrated from a top view. Additionally, none of the figures are drawn to scale.

FIG. 11 illustrates a substrate 101, a patterned resist layer 902, an annular pattern 901, and an annular trench 1101 in accordance with an embodiment. The annular trench 1101 can be produced by subjecting a substrate 101 with a patterned resist layer 902, as illustrated in FIGS. 9 and 10, to an etching process such as reactive ion etching. This is more commonly referred to as deep reactive ion etching (DRIE) by those familiar with the process. The annular trench 1101 is not drawn to scale because, in practice, an annular trench 1101 can be a few micrometers wide and can be deep enough to pass through or almost through the bottom side of the substrate 101.

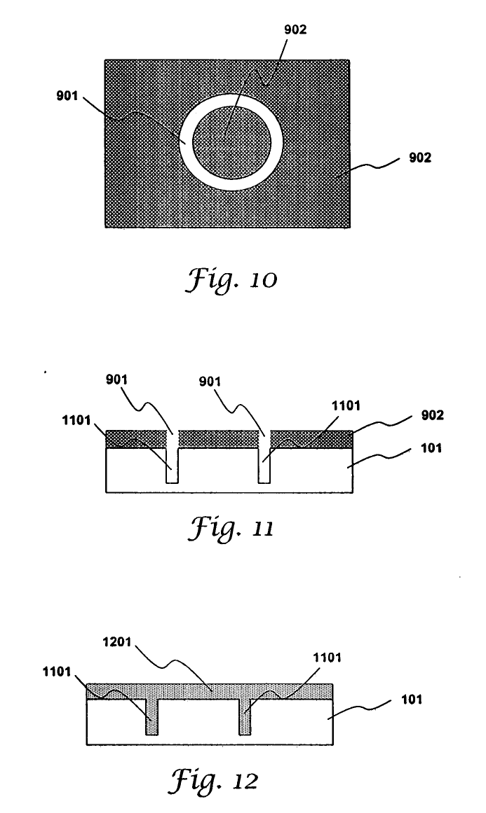

FIG. 12 illustrates a substrate 101, an annular trench 1101, and an insulating material 1201 deposited or thermally grown over the substrate 101 and in the annular trench 1101 in accordance with an embodiment. The structure of FIG. 12 can be produced from that illustrated in FIG. 11 by stripping the resist layer 301 and depositing the insulating material 1201. The insulating material 1201 can fill the annular trench 1101 and can also coat the substrate 101.

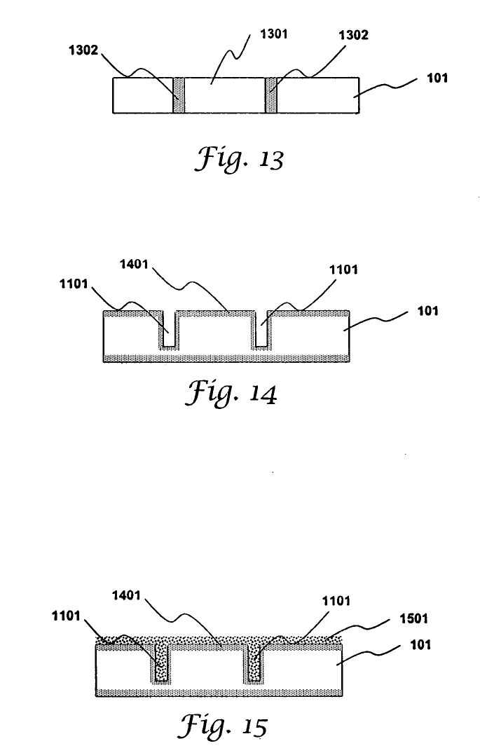

FIG. 13 illustrates a substrate 101, an annular insulating ring 1302, and a TTW connection 1301 in accordance with an embodiment. The structure illustrated in FIG. 13 can be produced from that illustrated in FIG. 12 by grinding the substrate 101 back side and polishing the substrate 101 front side and backside. The substrate 101 back side, which is the bottom side in the figures, is ground to expose the TTW connection 1301. The substrate 101 front side, illustrated as the top, can be polished to remove the coating of insulating material that was covering the top side of the TTW connection 1301. The TTW connection 1301 is electrically conductive because it is the same material as the substrate 101. The substrate 101 is electrically conductive because it is heavily doped.

FIG. 14 illustrates a silicon substrate 101 and an annular trench 1101 after oxidation in accordance with an embodiment. The structure of FIG. 14 can be produced from that of FIG. 11 by striping the resist layer 301 and oxidizing the remaining substrate. As discussed above, oxidizing a silicon substrate is a standard and well understood action in semiconductor processing. The result is that the substrate 101 and the trench 1101 have an oxide layer 1401 that can be a few micrometers thick. Oxide is not electrically conductive.

FIG. 15 illustrates a substrate 101 and an annular trench 1 101 after oxidation and after deposition of another material 1501 in accordance with an embodiment. The structure of FIG. 15 can be produced from that of FIG. 14 by depositing a layer of material 1501. Those skilled in the art of semiconductor processing know a variety of methods for depositing material such as vapor deposition, chemical vapor deposition, plasma enhance chemical vapor deposition, and others. The material 1501 fills the trench 1101 and coats the substrate 101. This material would most typically be polysilicon, but other materials could be used.

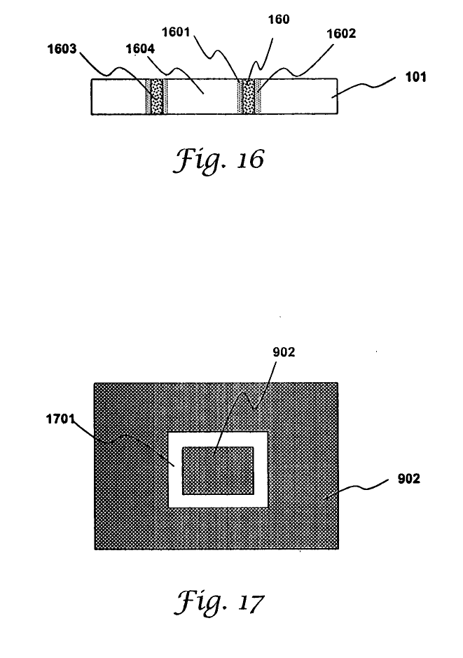

FIG. 16 illustrates a substrate 101, a filled annular volume 1603, and two annular insulating volumes in accordance with an embodiment. The structure of FIG. 16 can be produced from that of FIG. 15 by polishing the substrate 101 front side and grinding and polishing the substrate 101 back side. The substrate 101 back side is lapped or ground to remove the oxide layer 1401 and to expose the TTW connection 1604. It may also be polished if a smooth surface is required. The substrate front side is polished to remove the coating of material 1501 and the oxide layer 1401 and to thereby expose the TTW connection 1604.

FIG. 17 illustrates a silicon substrate, a resist layer 902, and a rectangular pattern 1701 as seen from above in accordance with an embodiment. The rectangular pattern from which the resist 1701 has been removed illustrates that a TTW connection does not have to be a circle or ellipse. Any other shape, such as a rectangle, a triangle or a similar polygon can be used.

In summary, the final structures illustrated in FIGS. 13 and 16 are plugs of conductive material running from one side of a substrate to the other. The plugs are ringed by electrically insulating material that insulates the plug from the substrate. In the structure of FIG. 16, the plug can also be ringed by other materials, such as polysilicon.

The embodiments call for producing an annular trench that is later filled with material to produce an annular ring or annular volume. The important property of an annulus is that it forms a volume that can enclose the TTW connection that s being formed. The circular nature of the annulus is not an important property. FIG. 17 illustrates a square shaped trench 1701, but is otherwise completely analogous to FIG. 10. A square trench 1701 can be used to form a square TTW connection. As such, a square trench 1701, triangular trench or other shaped trench is functionally equivalent to an annular trench.

It will be appreciated that variations of the above-disclosed and other features, aspects and functions, or alternatives thereof, may be desirably combined into many other different systems or applications. Also that various presently unforeseen or unanticipated alternatives, modifications, variations or improvements therein may be subsequently made by those skilled in the art which are also intended to be encompassed by the following claims.

What is claimed is:

1. A method comprising:
depositing a layer of resist over a first face of a silicon substrate that is heavily doped and using a photolithographic process to produce an annular pattern in the resist;
etching an annular trench into the silicon substrate as defined by the annular pattern;
filling the annular trench with an electrically insulating material and polishing the first face; and
polishing or grinding the faces of the silicon substrate to expose the filled annular trench thereby producing a low resistance connection through the substrate.

2. The method of claim 1 further comprising oxidizing the trench walls before filling the trench with electrically insulating material.

3. The method of claim 1 wherein the etching is reactive ion etching

4. The method of claim 1 further comprising:
creating an oxide layer on the first face of the silicon substrate before photolithographically producing the annular pattern and wherein the annular trench is etched through the oxide layer before it is etched into the silicon substrate.

5. The method of claim 1 wherein the first face of the silicon substrate is the front side of the silicon substrate which is also the polished side.

6. The method of claim 1 wherein the electrically insulating material is oxide.

7. The method of claim 1 further comprising oxidizing the trench walls before filling the trench with oxide.

8. A method comprising:
depositing a layer of resist over a first face of a silicon substrate that is heavily doped and using a photolithographic process to produce an annular pattern in the resist;
etching an annular trench into the silicon substrate as defined by the annular pattern;
creating an electrically insulating layer on the trench walls;
filling the annular trench with a fill material; and
polishing or grinding the faces of the silicon substrate to expose the filled annular trench thereby producing a low resistance connection through the substrate.

9. The method of claim 8 wherein the etching is reactive ion etching.

10. The method of claim 8 further comprising:
creating an oxide layer on the first face of the silicon substrate before photolithographically producing the annular pattern and wherein the annular trench is etched through the oxide layer before it is etched into the silicon substrate.

11. The method of claim 8 wherein the first face of the silicon substrate is the front side of the silicon substrate which is also the polished side.

12. The method of claim 8 wherein the fill material is polysilicon.

13. The method of claim 8 wherein the electrically insulating layer is an oxide layer that is created by oxidation of the trench walls.

14. The method of claim 8 wherein the electrically insulating layer is an oxide layer that is deposited.

15. A system comprising:
a silicon substrate that is heavily doped such that it is electrically conductive;
an annular trench through the silicon substrate wherein the annular trench reaches from one face of the silicon substrate to the other side of the silicon substrate; and
an electrically insulating material arranged in the trench to electrically insulate the inside of the annulus from the outside of the annulus, thereby producing an electrically conductive connection through the substrate.

16. The system of claim 15 wherein the electrically insulating material is oxide.

17. The system of claim 15 wherein the electrically insulating material completely fills the trench.

18. The system of claim 15 wherein the electrically insulating material completely coats at least one trench wall and further comprising a different material filling that portion of the trench that is not filled with the electrically insulating material.

19. The system of 15 wherein the electrically insulating material is oxide and oxide completely fills the trench.

20. The system of claim 15 wherein the electrically insulating material completely coats at least one trench wall and further comprising polysilicon filling that portion of the trench that is not filled with the electrically insulating material.
